(19) United States
(12) Patent Application Publication
(10) Pub. No.: US 2005/0097430 A1
(43) Pub. Date: May 5, 2005

(54) MAP decoder having a simple design and decoding method thereof

(76) Inventor: Eui-jun Park, Seoul (KR)

Correspondence Address: STANZIONE & KIM, LLP, 1740 N STREET, N.W., FIRST FLOOR, WASHINGTON, DC, 20036, US

(21) Appl. No.: 10/896,882

(22) Filed: Jul. 23, 2004

(30) Foreign Application Priority Data
Nov. 4, 2003 (KR) 2003-77515

(51) Int. Cl. H03M 13/03

(52) U.S. Cl. 714/792

(57) ABSTRACT

A MAP decoder having a simple design and a decoding method thereof. The MAP decoder includes an intrinsic information storage unit to store input intrinsic information, a branch metric operation unit to calculate branch metrics of a received signal, a branch metric storage unit to store the branch metrics calculated with respect to the received signal, a forward metric operation unit to calculate forward metrics by reading out the intrinsic information and the branch metrics corresponding to the received signal from the intrinsic information storage unit and the branch metric storage unit, respectively In addition, included is a backward metric operation unit to calculate backward metrics by reading out the intrinsic information and the branch metrics corresponding to the received signal from the intrinsic information storage unit and the branch metric storage unit, respectively, and a log likelihood ratio (LLR) unit to calculate an LLR using the intrinsic information, the branch metrics and the backward metrics corresponding to the received signal. According to the MAP decoder adopting the proposed MAP algorithm, the implementation of operational elements can be simplified, and memory space can efficiently be reduced.

### CROSS-REFERENCE TO RELATED APPLICATIONS

This application claims the benefit of Korean Patent Application No. 2003-77515 filed with the Korea Industrial Property Office on Nov. 4, 2003, the disclosure of which is incorporated herein by reference.

### BACKGROUND OF THE INVENTION

1. Field of the Invention

The present general inventive concept relates to an error correction decoder used with a communication system, and more particularly, to a MAP (Maximum A Posteriori) decoder and a decoding method thereof.

2. Description of the Related Art

Turbo code has recently been adopted by the ITU as the standard of a channel code for high-rate data transmission in the next-generation mobile communication protocols such as IMT-2000. The Turbo code proposed by Berrou at al. becomes a matter of great concern and interest by its epoch-making performance in a low signal-to-noise ratio of 0.7 dB during its 18-times iterative decoding operation. Turbo code also has a relatively simple decoding algorithm in an additive white Gaussian noise (AWGN) environment. Also, the Turbo code is known as a strong coding technique reliable even in a fading channel.

The Turbo code shows a better performance according to a number of iterations and the size of interleavers. Accordingly, research is actively in progress regarding interleavers that greatly affect the performance of the Turbo code mainly in CDMA200 and ARIB.

FIGS. 1A and 1B illustrate Turbo trellis-coded modulation (TTCM) encoders. Specifically, FIG. 1A shows a construction of a 16 QAM TTCM encoder, and FIG. 1B shows the construction of a 64 QAM TTCM encoder.

The Turbo code comprises convolutional codes connected by interleavers. The whole TTCM structure is similar to the binary-operational Turbo code. Here, TTCMs are connected through bit interleavers so that the TTCMs can be iteratively decoded in a unit of a bit.

A respective connected convolutional encoder has a code rate of b/(b+1), and its output b+1 is mapped by a 2^{b+1} level modulation. The output b+1 of the first encoder is mapped by in-phase (I) levels, the number of which is 2^{b+1}, and the output bit number b+1 of the second encoder is mapped by quadrature (Q) levels, the number of which is 2^{b+1}. Thus, the outputs of the two encoders have the 2^{2b+1} QAM signal form.

A well-known Turbo code decoding system is a MAP (Maximum A Posteriori) algorithm.

A signal R₁^{N} received in the Turbo decoder is defined by
R₁^{N}=(R₁, R₂, . . . , Rₖ, . . . , R_{N})
where, N is the number of symbols in a frame.

Rₖ=(xₖ,yₖ) denote symbols received at the time of k, and are defined by
xₖ=Xₖ+iₖ
yₖ=Yₖ+qₖ
where, Xₖ and Yₖ are encoded symbols, and iₖ and qₖ are additive white Gaussian noise having a variance of σ². Xₖ and Yₖ can be determined by mapping the encode output bits according to the modulation system.

A log likelihood ratio (LLR), which can represent the reliability according to the result of decoding, can be defined by the following Equation 1. At this time, L(dₖ^{q}) represents the LLR of the decoded data bit dₖ^{q}.

$$\begin{matrix}L ( {d}_{k}^{q} ) = log \frac{{\sum }_{i \vert {d}_{k}^{q} = 1}^{} Pr ( {d}_{k} = i \vert {R}_{1}^{N} )}{{\sum }_{i \vert {d}_{k}^{q} = 0}^{} Pr ( {d}_{k} = i \vert {R}_{1}^{N} )} , \\ {d}_{1} = ( {d}_{k}^{1} , ⋯ , {d}_{k}^{q} , ⋯ , {d}_{k}^{n} )\end{matrix} \qquad Equation 1$$

If Sₖ is the state of the encoder, and λₖⁱ=Pr(dₖ, Sₖ=m|R₁^{N}), Equation 1 can be expressed by Equation 2 below:

$$L ( {d}_{k}^{q} ) = log \frac{{\sum }_{i \vert {d}_{k}^{q} = 1}^{} {\sum }_{m} {λ}_{k}^{i}}{{\sum }_{i \vert {d}_{k}^{q} = 1}^{} {\sum }_{m} {λ}_{k}^{i}} \qquad Equation 2$$

If the LLR is L(dₖ^{q})≧0 as a result of measuring the reliability, it is determined that d′ₖ^{q}=1, while if the LLR is L(dₖ^{q})≦0, it is determined that d′ₖ^{q}=0.

Meanwhile, forward metrics αₖ(m), backward metrics βₖ(m), and branch metrics γᵢ(Rₖ,m′,m) can be defined by Equation 3 below:

$$\begin{matrix}{α}_{k} ( m ) = Pr ( {S}_{k} = m \vert {R}_{k}^{m} ) , \\ {β}_{k} ( m ) = \frac{Pr ( {R}_{k + 1}^{N} \vert {S}_{k} = m )}{Pr ( {R}_{k + 1}^{N} \vert {R}_{1}^{N} )} , \\ {γ}_{i} ( {R}_{k} , {m}^{′} , m ) = Pr ( {d}_{k} = i , {S}_{k} = m , {R}_{k} \vert {S}_{k - 1} = {m}^{′} ) .\end{matrix} \qquad Equation 3$$

Using the forward metrics αₖ(m), the backward metrics βₖ(m), and the branch metrics γᵢ(Rₖ,m′,m) defined in Equation 3 for the decoding operation, the LLR L(dₖ^{q}) can be defined by Equation 4 below:

$$L ( {d}_{k}^{q} ) = log \frac{{\sum }_{i \vert {d}_{k}^{q} = 1}^{} {\sum }_{m} {\sum }_{{m}^{′}} {γ}_{i} ( {R}_{k} , {m}^{′} , m ) {α}_{k - 1} ( {m}^{′} ) {β}_{k} ( m )}{{\sum }_{i \vert {d}_{k}^{q} = 1}^{} {\sum }_{m} {\sum }_{{m}^{′}} {γ}_{i} ( {R}_{k} , {m}^{′} , m ) {α}_{k - 1} ( {m}^{′} ) {β}_{k} ( m )} \qquad Equation 4$$

Also, the forward metrics αₖ(m) and the backward metrics βₖ(m) can be defined by Equation 5 below:

$$\begin{matrix}{α}_{k} = {\sum }_{{m}^{′}} {\sum }_{i} {γ}_{i} ( {R}_{k} , {m}^{′} , m ) {α}_{k - 1} ( {m}^{′} ) , \\ {β}_{k} = {\sum }_{{m}^{′}} {\sum }_{i} {γ}_{i} ( {R}_{k + 1} , {m}^{′} , m ) {β}_{k + 1} ( {m}^{′} )\end{matrix} \qquad Equation 5$$

If the previous state value determined by an encoder input dₖ=i and a state Sₖ=m is S_{b}ⁱ(m), the branch metrics γᵢ(Rₖ,m′,m) of Equation 5 can be defined by Equation 6 below:

$${γ}_{i} ( {R}_{k} , {m}^{′} , m ) = \{ \begin{matrix}{σ}_{i} ( {R}_{k} , m ) ; & {m}^{′} = {S}_{b}^{i} ( m ) \\ 0 ; & {m}^{′} \neq {S}_{b}^{i} ( m )\end{matrix} \qquad Equation 6$$

At this time, δᵢ(Rₖ,m)=Pr(dₖ=i,Sₖ=m)/2, and γᵢ(Rₖ₊₁, m,m′) can be defined by Equation 7 below:

$${γ}_{i} ( {R}_{k + 1} , m , {m}^{′} ) = \{ \begin{matrix}{σ}_{i}^{- 1} ( {R}_{k + 1} , m ) ; & {m}^{′} = {S}_{n}^{i} ( m ) \\ 0 ; & {m}^{′} \neq {S}_{n}^{i} ( m )\end{matrix} \qquad Equation 7$$

At this time, Sₙⁱ(m) is the next state value determined by the state Sₖ=m and the encoder input dₖ₊₁=i.

Accordingly, if σ² is the variance of the AWGN channel environment, the branch metrics δᵢ(Rₖ,m) can be defined by Equation 8 below:

$${δ}_{i} ( {R}_{k} , m ) = \frac{1}{2 \sqrt{2 π σ}} exp ( - \frac{1}{2 {σ}^{2}} {( {x}_{k} - {X}_{k} )}^{2} ) \qquad Equation 8$$

The Turbo decoding is performed through calculation of the forward metrics and the backward metrics based on the branch metrics δᵢ(Rₖ,m) defined by Equation 8.

The Turbo decoder using the conventional MAP algorithm, in order to obtain the backward metric values, should perform a reverse trace with respect to the whole received frames, and then perform a forward LLR calculation using the value, resulting in that a memory to store the branch metrics and the backward metrics is required.

Accordingly, the turbo decoder using the conventional MAP algorithm has the drawbacks in that a large-capacity memory is required to perform the calculation in the unit of a frame.

### SUMMARY OF THE INVENTION

Accordingly, it is an aspect of the present general inventive concept to solve the above and/or other drawbacks and problems associated with the conventional arrangement.

Another aspect of the present general inventive concept is to provide a MAP (Maximum A Posteriori) decoder and a decoding method thereof that can reduce a number of operational elements and an amount of operations by using a proposed MAP algorithm, and also can efficiently reduce a memory space required for the operation.

Additional aspects and advantages of the present general inventive concept will be set forth in part in the description which follows and, in part, will be obvious from the description, or may be learned by practice of the present general inventive concept.

The foregoing and/or other aspects and features of the generative inventive concept can be achieved by providing a MAP decoder including an intrinsic information storage unit to store input intrinsic information, a branch metric operation unit to calculate branch metrics of a received signal, a branch metric storage unit to store the branch metrics calculated with respect to the received signal, a forward metric operation unit to calculate forward metrics by reading out the intrinsic information and the branch metrics corresponding to the received signal from the intrinsic information storage unit and the branch metric storage unit, respectively, a backward metric operation unit to calculate backward metrics by reading out the intrinsic information and the branch metrics corresponding to the received signal from the intrinsic information storage unit and the branch metric storage unit, respectively, and a log likelihood ratio (LLR) unit to calculate an LLR using the intrinsic information, the branch metrics and the backward metrics corresponding to the received signal.

In an aspect of the present general inventive concept, the MAP decoder can further include a backward metric storage unit to store the backward metrics calculated by the backward metric operation unit.

In a further aspect of the general inventive concept, the branch metric storage unit can include a memory space to store the branch metrics, the number of which is N2^{b+1} on the condition that a frame length of the received signal is N and the number of input bits of an encoder is 2b, and the forward metric operation unit, the backward metric operation unit and the LLR unit iteratively read out the branch metrics, the number of which is N2^{b+1} for a predetermined number of times in response to the received signal to use the branch metrics.

In an aspect of the general inventive concept, the intrinsic information storage unit can include a memory space to store the intrinsic information metrics, the number of which is N2^{2b} on condition that a frame length of the received signal is N and the number of input bits of an encoder is 2b.

In still a further aspect of the present general inventive concept, the branch metrics Bₖⁱ(m) can be expressed, on a condition that Xₖⁱ(m) is an output of an encoder determined by a state Sₖ₋₁=m and an encoder input dₖ=i, and Rₖ=(xₖ,yₖ) is a signal received at a time of k, by the following equation:

$$\begin{matrix}{B}_{k}^{i} ( m ) = {σ}_{i} ( {R}_{k} , m ) \\ = K exp ( \frac{2}{2 {σ}^{2}} {X}_{k}^{i} ( m ) ( {x}_{k} - {X}_{k}^{i} ( m ) + ( {2}^{b + 1} - 1 ) ) )\end{matrix}$$

wherein K denotes a constant, and b denotes a half of the number of encoder input bits.

In still a further aspect of the present general inventive concept, the forward metrics αₖ(m), calculated using the branch metrics Bₖⁱ(m), can be expressed by the following equation:

$${α}_{k} ( m ) = {\sum }_{i} {B}_{k}^{i} ( m ) {Intr}_{k}^{i} {α}_{k - 1} ( {S}_{b}^{i} ( m ) )$$

wherein S_{b}ⁱ(m) denotes a previous state determined by an encoder input dₖ=i and a state Sₖ=m, and Intrₖⁱ denotes the intrinsic information.

In still a further aspect of the present general inventive concept, the backward metrics, βₖ(m) calculated using the branch metrics Bₖⁱ(m), can be expressed by a following equation:

$${β}_{k} ( m ) = {\sum }_{i} {{B}_{k + 1}^{i} ( m )}^{- 1} {Intr}_{k + 1}^{i} {β}_{k - 1} ( {S}_{n}^{i} ( m ) )$$

wherein Sₙⁱ(m) denotes a next state determined by an encoder input dₖ₊₁=i and a state Sₖ=m, and Intrₖⁱ denotes the intrinsic information.

The LLR L(dₖ^{q}), calculated using the branch metrics Bₖⁱ(m), the forward metrics αₖ(m), and the backward metrics βₖ(m), can be expressed by a following equation:

$$L ( {d}_{k}^{q} ) = log \frac{{\sum }_{i \vert {d}_{k}^{q} = 1} {\sum }_{m} {B}_{k}^{i} ( m ) {Intr}_{k}^{i} {α}_{k - 1} ( {S}_{b}^{i} ( m ) ) {β}_{k} ( m )}{{\sum }_{i \vert {d}_{k}^{q} = 0} {\sum }_{m} {B}_{k}^{i} ( m ) {Intr}_{k}^{i} {α}_{k - 1} ( {S}_{b}^{i} ( m ) ) {β}_{k} ( m )}$$

The foregoing and/or other aspects of the present general inventive concept can also be achieved by providing a decoding method used with a MAP decoder including the operations of storing input intrinsic information, calculating branch metrics of a received signal, storing the branch metrics calculated with respect to the received signal, calculating forward metrics by reading out the intrinsic information and the branch metrics corresponding to the received signal, calculating backward metrics by reading out the intrinsic information and the branch metrics corresponding to the received signal, and calculating a log likelihood ratio (LLR) using the intrinsic information, the branch metrics and the backward metrics corresponding to the received signal.

In an aspect of the present general inventive concept, the number of the branch metrics stored on the condition that a frame length of the received signal is N and the number of input bits of an encoder is 2b is N2^{b+1}, the branch metrics, the number of which is N2^{b+1}, are iteratively read out a predetermined number of times in response to the received signal to use the branch metrics when the forward metrics, the backward metrics and the LLR are calculated, and the number of the stored intrinsic information is N2^{b}.

Accordingly, a MAP decoder and a decoding method thereof, which can reduce the number of operational elements and the number of operations and also can efficiently reduce a memory space used to perform the operations, can be provided.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1A is a view illustrating the construction of a general 16QAM TTCM encoder;

FIG. 1B is a view illustrating the construction of a general 64QAM TTCM encoder;

FIG. 2 is a schematic block diagram of a Turbo decoder according to an embodiment of the present general inventive concept;

FIG. 3 is a schematic block diagram of a MAP decoder to which a MAP algorithm is applied, according to another embodiment of the present general inventive concept; and

FIG. 4 is a flowchart illustrating a decoding method used with a MAP decoder of FIG. 3.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

First, with reference to several equations below, a MAP algorithm proposed according to an embodiment of the present general inventive concept will be explained in detail.

Branch metrics δ(Rₖ,m) can be calculated as defined in equation 8 below (as recited above as well):

$${δ}_{i} ( {R}_{k} , m ) = \frac{1}{2 \sqrt{2 π σ}} exp ( - \frac{1}{2 {σ}^{2}} {( {x}_{k} - {X}_{k} )}^{2} ) \qquad Equation 8$$

For example, if output bits of a 64 QAM TTCM encoder having a code rate of ⅔ are I₀, I₁, and I₂, a mapped symbol Xₖ is given by Equation 9 below:
Xₖ=4(2I₀−1)+2(2I₁−1)+(2I₂−1) Equation 9

Using Xₖ, the branch metrics defined by Equation 8 can be expressed by Equation 10 below:

$$\begin{matrix}{δ}_{i} ( {R}_{k} , m ) = \frac{1}{2 \sqrt{2 π σ}} exp ( - \frac{1}{2 {σ}^{2}} {( {x}_{k} - {X}_{k} )}^{2} ) \\ = {K}_{a} exp ( \frac{1}{2 {σ}^{2}} 2 x ( 4 ( 2 {I}_{0} - 1 ) + 2 ( 2 {I}_{1} - 1 ) + \\ ( 2 {I}_{2} - 1 ) ) - \frac{1}{2 {σ}^{2}} ( 4 ( 2 {I}_{0} - 1 ) + \\ { 2 ( 2 {I}_{1} - 1 ) + ( 2 {I}_{2} - 1 ) )}^{2} ) \\ = {K}_{a} exp ( \frac{1}{2 {σ}^{2}} ( 2 {x}_{k} ( 2 ( 4 {I}_{0} + 2 {I}_{1} + {I}_{2} ) - 7 ) - \\ {( 2 ( 4 {I}_{0} + 2 {I}_{1} + {I}_{2} ) - 7 )}^{2} ) )\end{matrix} \qquad Equation 10$$

Reducing the received signal and the constant from Equation 10 can result in Equation 11 as provided below:

$$\begin{matrix}{σ}_{i} ( {R}_{k} , m ) = {K}_{b} exp ( \frac{1}{2 {σ}^{2}} ( 2 {x}_{k} ( 2 ( 4 {I}_{0} + 2 {I}_{1} + {I}_{2} ) ) - \\ \frac{1}{2 {σ}^{2}} ( {( 2 ( 4 {I}_{0} + 2 {I}_{1} + {I}_{2} ) )}^{2} - \\ 28 ( 4 {I}_{0} + 2 {I}_{1} + {I}_{2} ) ) ) \\ = {K}_{b} exp ( \frac{2}{2 {σ}^{2}} ( 4 {I}_{0} + 2 {I}_{1} + {I}_{2} ) ( {x}_{k} - 4 {I}_{0} + \\ 2 {I}_{1} + {I}_{2} ) + 7 ) )\end{matrix} \qquad Equation 11$$

If (4I₀+2I₁+I₂) is defined as Xₖⁱ(m), Xₖⁱ(m) becomes the output of the encoder determined by the state Sₖ₋₁=m and the encoder input dₖ=i. Using Xₖⁱ(m), the branch metrics of Equation 11 can simply be reduced as illustrated by Equation 12 below:

$${σ}_{i} ( {R}_{k} , m ) = {K}_{b} exp ( \frac{2}{2 {σ}^{2}} {X}_{k}^{i} ( m ) ( {x}_{k} - {X}_{k}^{i} ( m ) + 7 ) ) \qquad Equation 12$$

Meanwhile, if the output bits of the 16QAM TTCM encoder having a code rate of ½ are I₀ and I₁, the mapped symbol Xₖ would be Xₖ=2(2I₀−1)+(2I₁−1), and using this, the branch metrics can be reduced by a following Equation 13 below:

$$\begin{matrix}{δ}_{i} ( {R}_{k} , m ) = {K}_{b} exp ( \frac{2}{2 {σ}^{2}} ( 2 {I}_{0} + {I}_{1} ) ( {x}_{k} - ( 2 {I}_{0} + {I}_{1} ) + \\ 3 ) ) ) \\ = {K}_{b} exp ( \frac{2}{2 {σ}^{2}} {X}_{k}^{i} ( m ) ( {x}_{k} - {X}_{k}^{i} ( m ) + 3 ) )\end{matrix} \qquad Equation 13$$

As described above, according to the MAP algorithm according to an embodiment of the present general inventive concept, the branch metrics can be simply arranged as in Equations 12 and 13.

For example, if the number of bits of Xₖⁱ(m) with respect to the 64 QAM TTCM decoder having a code rate of ⅔ is 3, and the number of bits of the signal xₖ received in the decoder is 8, then a 3×8 multiplier is typically needed according to the proposed MAP algorithm of the present general inventive concept, while an 8×8 multiplier is required according to the conventional MAP algorithm (See Equation 8).

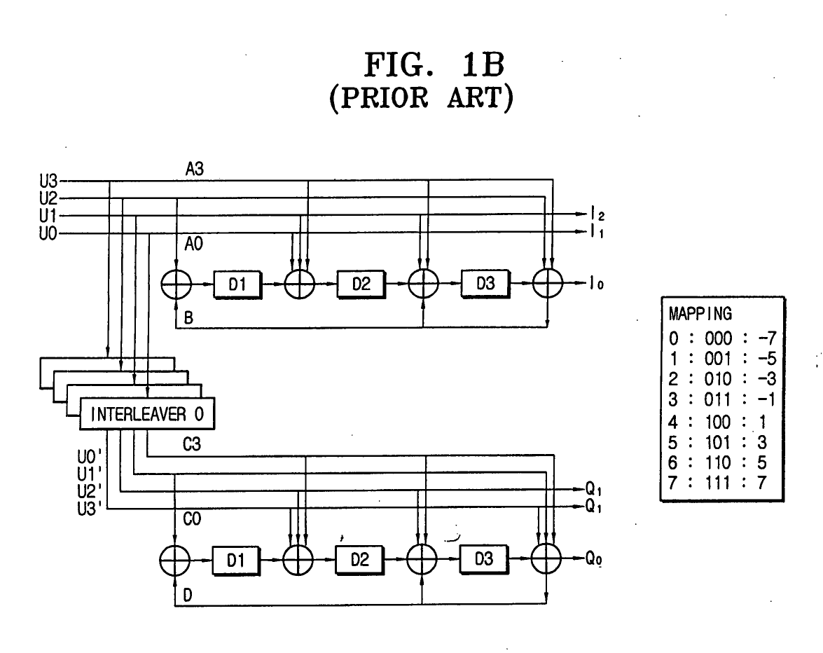

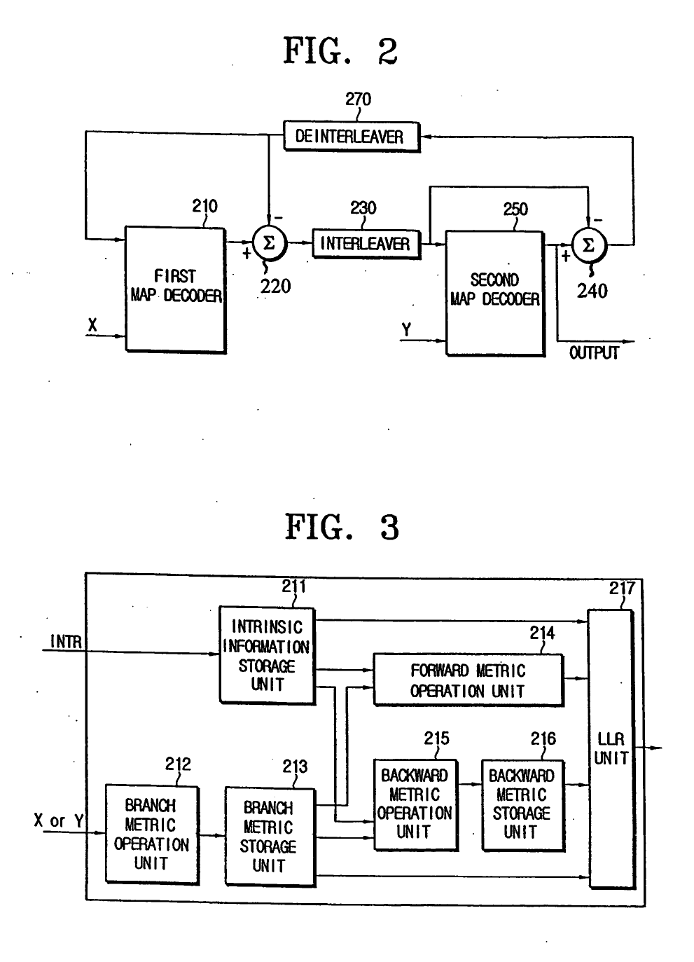

Accordingly, by applying the MAP algorithm of the present general inventive concept to a decoder as will be discussed with regard to FIGS. 2 and 3 below, the implementation of operation elements for the forward metrics, backward metrics and LLR calculated based on the branch metrics can be simplified.

Hereinafter, the branch metrics according to the MAP algorithm according to an embodiment of the present invention can be defined as Bₖⁱ(m), and the 16QAM TTCM decoder using the above algorithm will be explained in detail.

FIG. 2 is a schematic block diagram of a turbo decoder according to an embodiment of the present general inventive concept.

The Turbo decoder of FIG. 2 includes first and second MAP decoders 210 and 250, first and second subtracters 220 and 240, an interleaver 230 and a deinterleaver 270.

The first and second MAP decoders 210 and 250 are connected in series between the interleaver 230 and the deinterleaver 270, and can perform an iterative decoding. At this time, the first and second MAP decoders 210 and 250 can perform the decoding by applying the MAP algorithm according to the previously described embodiment, and an explanation of the respective MAP decoders is provided below.

The first MAP decoder 210 can receive an x signal and intrinsic information, and the second MAP decoder 250 can perform the decoding using a y signal and the intrinsic information that is provided from the previous output signal.

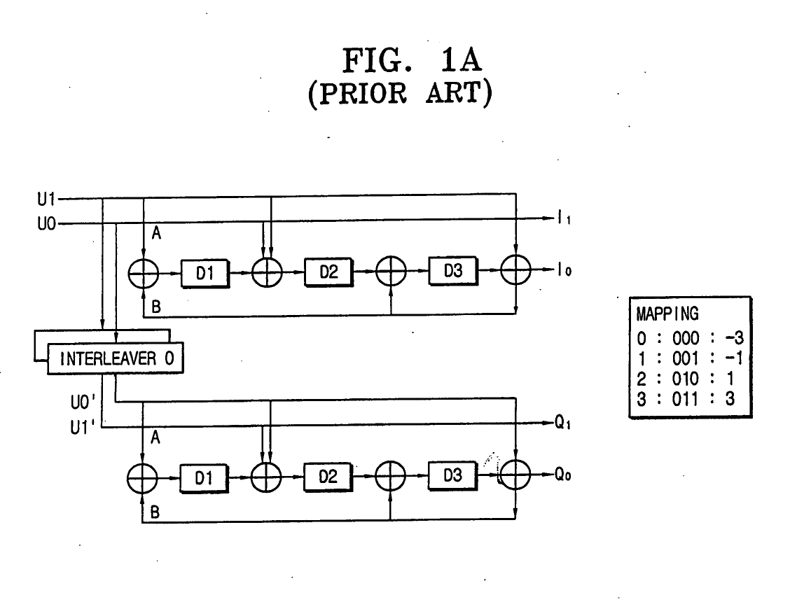

The interleaver 230 can handle the encoders illustrated in FIGS. 1A and 1B, and can perform an interleaving operation when the intrinsic information is transmitted from the first MAP decoder 210 to the second MAP decoder 250.

In contrast, the deinterleaver 270 can perform a deinterleaving when the intrinsic information is transmitted from the second MAP decoder 250 to the first MAP decoder 210.

The first and second subtracters 220 and 240 receive information from the first map decoder 210 and the deinterleaver 270, and the interleaver 230 and the second map decoder 250, respectively, and can subtract the respective intrinsic information received in order to prevent an overflow when the first and second MAP decoders 210 and 250 mutually transfer the intrinsic information.

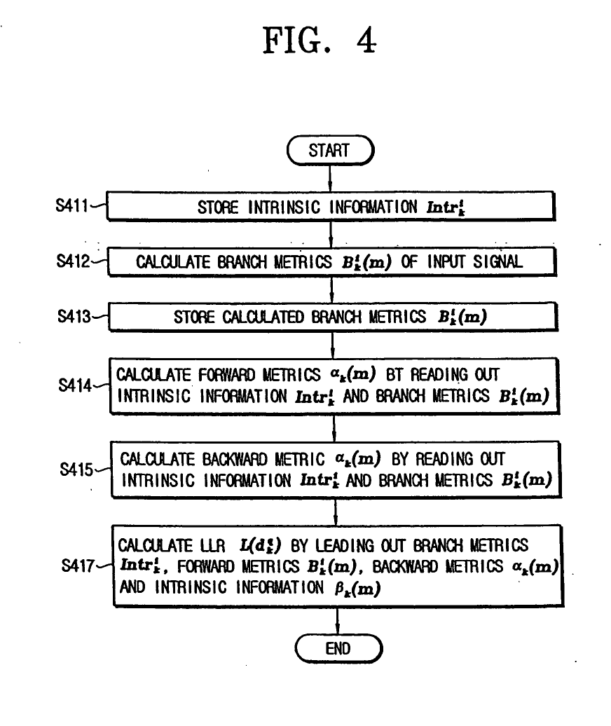

FIG. 3 is a schematic block diagram of the MAP decoder 210 according to another embodiment of the present general inventive concept. FIG. 4 is a flowchart illustrating a corresponding decoding method executed by the map decoder illustrated in FIG. 3. The decoding method illustrated in FIG. 4 and described above is performed by the first and second MAP decoders 210 and 250, which will now be explained in detail.

The MAP decoder of FIG. 3. can include an intrinsic information storage unit 211, a branch metric operation unit 212, a branch metric storage unit 213, a forward metric operation unit 214, a backward metric operation unit 215, a backward metric storage unit 216, and an LLR unit 217.

The intrinsic information storage unit 211 can store the intrinsic information Intrₖⁱ corresponding to the received signal (operation S411). Accordingly, the size of the intrinsic information storage unit 211 can be N2^{2b}. Thus, in the case of the 16 QAM, the size becomes N2² since b=1. Here, ‘N’ denotes a frame length, and ‘2b’ the number of bits of the signal inputted to the encoder at a certain time of k.

The branch metric operation unit 212 can calculate branch metrics Bₖⁱ(m) of the received signal (x or y signal) (in operation S412), such that Equations 12 and 13 can be applied to Equation 14 below:

$$\begin{matrix}{B}_{k}^{i} ( m ) = {σ}_{i} ( {R}_{k} , m ) \\ = K exp ( \frac{2}{2 {σ}^{2}} {X}_{k}^{i} ( m ) ( {x}_{k} - {X}_{k}^{i} ( m ) + ( {2}^{b + 1} - 1 ) ) )\end{matrix} \qquad Equation 14$$

Here, ‘K’ denotes a constant, and ‘b’ a half of the number of input bits of the encoder. For example, in the case of 16QAM, b=1, while in the case of 64QAM, b=2.

The branch metric storage unit 213 can store the branch metrics Bₖⁱ(m) calculated by the branch metric operation unit 212, and the size thereof is N2^{b+1} (operation S413). Here, ‘N’ denotes a frame length, and ‘2b’ the number of bits of the signal inputted to the encoder at a certain time of k. Thus, ‘b’ becomes ½ of the number of bits of the input signal.

Specifically, in the case that the number of memories of the encoder is v, and the number of bits of the input signals is 2b, the number of output signals of the encoder becomes 2^{v}×2^{2b}. Among the 2^{v}×2^{2b} output signals, one output level is iterated

$$\frac{{2}^{v} \times {2}^{2 b}}{{2}^{b + 1}}$$

times, considering the number 2^{b+1} of output levels of the encoder.

Table 1 below shows input signals (in), states (s) and signals (out) mapped by output signals of a 16 QAM TTCM encoder having three memories.

TABLE 1

| in | s | out | in | s | out | in | s | out | in | s | Out |
|---|---|---|---|---|---|---|---|---|---|---|---|
| 0 | 0 | −3 | 0 | 2 | −3 | 0 | 4 | −3 | 0 | 6 | −3 |
| 1 | | 1 | 1 | | 1 | 1 | | 1 | 1 | | 1 |
| 2 | | −1 | 2 | | −1 | 2 | | −1 | 2 | | −1 |
| 3 | | 3 | 3 | | 3 | 3 | | 3 | 3 | | 3 |
| 0 | 1 | −1 | 0 | 3 | −1 | 0 | 5 | −1 | 0 | 7 | −1 |
| 1 | | 3 | 1 | | 3 | 1 | | 3 | 1 | | 3 |
| 2 | | −3 | 2 | | −3 | 2 | | −3 | 2 | | −3 |
| 3 | | 1 | 3 | | 1 | 3 | | 1 | 3 | | 1 |

As shown in Table 1, the total number of mapped signals (out) is 2²×2³ in the case that the number of input signals (in) is 2², and the number of states is 2³. One level of the mapped signals (out) is iterated

$$\frac{{2}^{2} \times {2}^{3}}{{2}^{2}}$$

times, i.e., 2³ times.

Accordingly, the branch metric storage unit 213 can have a memory size of N2^{b+1} that corresponds to the number of bits of the output signal of the encoder, and thus only one storing operation may be performed with respect to the iterative branch metrics. The forward metric operation unit 214, the backward metric operation unit 215, and the LLR unit 217, which use the branch metrics, can iteratively read out the pre-stored branch metrics corresponding to the received signal a predetermined number of times.

The forward metric operation unit 214 can calculate the forward metrics αₖ(m) using the intrinsic information and the branch metrics stored in the intrinsic information storage unit 211 and the branch metric storage unit 213, respectively (operation S414). At this time, the intrinsic information and the branch metric information read out the intrinsic information Intrₖⁱ and the branch metrics Bₖⁱ(m) corresponding to the received signal. The forward metrics αₖ(m) are defined by Equation 15 below:

$${α}_{k} ( m ) = {\sum }_{i} {B}_{k}^{i} ( m ) {Intr}_{k}^{i} {α}_{k - 1} ( {S}_{b}^{i} ( m ) ) \qquad Equation 15$$

The backward metric operation unit 215 can calculate the backward metrics Bₖ(m) using the intrinsic information and the branch metrics stored in the intrinsic information storage unit 211 and the branch metric storage unit 213, respectively (operation S415). The intrinsic information and the branch metric information read out the intrinsic information Intrₖⁱ and the branch metrics Bₖⁱ(m) corresponding to the received signal. The backward metrics βₖ(m) can be defined by Equation 16 below:

$${β}_{k} ( m ) = {\sum }_{i} {{B}_{k + 1}^{i} ( m )}^{- 1} {Intr}_{k + 1}^{i} {β}_{k - 1} ( {S}_{n}^{i} ( m ) ) \qquad Equation 16$$

The backward metric storage unit 216 can store the calculated backward metrics βₖ(m) in the unit of a frame (operation S416). Accordingly, when the LLR is calculated, the backward metrics are read out in synchronization with the branch metrics and the forward metrics.

The LLR unit 217 can calculate the LLR L(dₖ^{q}) using the branch metrics Bₖⁱ(m), the forward metrics αₖ(m), the backward metrics βₖ(m), and the intrinsic information Intrₖⁱ (operation S417). Of course, the intrinsic information Intrₖⁱ and the branch metrics Bₖⁱ(m) correspond to the received signal. The LLR L(d_{q}^{q}) can be defined by Equation 17 below:

$$L ( {d}_{k}^{q} ) = log \frac{{\sum }_{i \vert {d}_{k}^{q} = 1}^{} {\sum }_{m} {B}_{k}^{i} ( m ) {Intr}_{k}^{i} {α}_{k - 1} ( {S}_{b}^{i} ( m ) ) {β}_{k} ( m )}{{\sum }_{i \vert {d}_{k}^{q} = 0}^{} {\sum }_{m} {B}_{k}^{i} ( m ) {Intr}_{k}^{i} {α}_{k - 1} ( {S}_{b}^{i} ( m ) {β}_{k} ( m )} \qquad Equation 17$$

The LLR L(dₖ^{q}) calculated by the LLR unit 217 can be inputted to the next MAP decoder as the intrinsic information.

Accordingly, by applying the MAP algorithm according to an embodiment of the present general inventive concept to the decoders, the implementation of operation elements to calculate the branch metrics, the forward metrics, the backward metrics and the LLR, can be simplified.

Meanwhile, the decoder illustrated in FIG. 2 and FIG. 3 requires a memory space of N2^{b+1} to store the branch metrics, and the memory space of N2^{2b} to store the intrinsic information, that is, the whole memory space of N2^{b-1}+N2^{2b}.

By contrast, the conventional decoder requires the whole memory space of N2^{v}2^{2b} to store the branch metrics and the intrinsic information, wherein v is the number of memories of the decoder.

Accordingly, embodiments of the present general inventive concept can efficiently reduce the memory space of the decoder.

As described above in certain embodiments of the present general inventive concept, by applying the proposed MAP algorithm, the implementation of operation elements to calculate the branch metrics, the forward metrics, the backward metrics and the LLR can also be simplified.

Also, the whole memory space of the decoder can efficiently be reduced through preparing of the memory space for the branch metrics and the memory space for the intrinsic information, respectively, and reducing of the memory space of the branch metrics.

The MAP algorithm described herein can is not required to be used in its entirety, but can be used in many embodiments, including any combination of the formulas described herein.

Although a few embodiments of the present general inventive concept have been shown and described, it will be appreciated by those skilled in the art that changes may be made in these embodiments without departing from the principles and spirit of the invention, the scope of which is defined in the appended claims and their equivalents.

1. A MAP decoder comprising:
an intrinsic information storage unit to store input intrinsic information;
a branch metric operation unit to calculate branch metrics of a received signal;
a branch metric storage unit to store the branch metrics calculated with respect to the received signal;
a forward metric operation unit to calculate forward metrics by reading out the intrinsic information and the branch metrics corresponding to the received signal from the intrinsic information storage unit and the branch metric storage unit, respectively;
a backward metric operation unit to calculate backward metrics by reading out the intrinsic information and the branch metrics corresponding to the received signal from the intrinsic information storage unit and the branch metric storage unit, respectively; and
a log likelihood ratio (LLR) unit to calculate an LLR using the intrinsic information, the branch metrics and the backward metrics corresponding to the received signal.

2. The MAP decoder as claimed in claim 1, further comprising a backward metric storage unit to store the backward metrics calculated by the backward metric operation unit.

3. The MAC decoder as claimed in claim 1, wherein the branch metric storage unit has a memory space to store the branch metrics the number of which is N2^{b+1} on the condition that a frame length of the received signal is N and the number of input bits of an encoder is 2b; and
wherein the forward metric operation unit, the backward metric operation unit and the LLR unit iteratively read out the branch metrics the number of which is N2^{b+1} for a predetermined number of times in response to the received signal to use the branch metrics.

4. The MAC decoder as claimed in claim 1, wherein the intrinsic information storage unit has a memory space to store the intrinsic information metrics the number of which is N2^{2b} on the condition that a frame length of the received signal is N and the number of input bits of an encoder is 2b.

5. The MAP decoder as claimed in claim 1, wherein the branch metrics Bₖⁱ(m) are expressed on a condition that Xₖⁱ(m) is an output of an encoder determined by a state Sₖ₋₁=m and an encoder input dₖ=i, and Rₖ=(xₖ, yₖ) is a signal received at a time of k, by the following equation:
$${B}_{k}^{i} ( m ) = {σ}_{i} ( {R}_{k} , m ) = K exp ( \frac{2}{2 {σ}^{2}} {X}_{k}^{i} ( m ) ( {x}_{k} - {X}_{k}^{i} ( m ) + ( {2}^{b + 1} - 1 ) ) ) ,$$
wherein K denotes a constant, and b denotes ½ of the number of encoder input bits.

6. The MAP decoder as claimed in claim 1, wherein the forward metrics αₖ(m), calculated using the branch metrics Bₖⁱ(m) are expressed by a following equation,
$${α}_{k} ( m ) = {\sum }_{i} {B}_{k}^{i} ( m ) {Intr}_{k}^{i} {α}_{k - 1} ( {S}_{b}^{i} ( m ) )$$
wherein S_{b}ⁱ(m) denotes a previous state determined by an encoder input dₖ=i and a state Sₖ=m, and Intrₖⁱ denotes the intrinsic information.

7. The MAP decoder as claimed in claim 1, wherein the backward metrics βₖ(m) calculated using the branch metrics Bₖⁱ(m) are expressed by a following equation,
$${β}_{k} ( m ) = {\sum }_{i} {{B}_{k + 1}^{i} ( m )}^{- 1} {Intr}_{k + 1}^{i} {β}_{k - 1} ( {S}_{n}^{i} ( m ) )$$
wherein Sₙⁱ(m) denotes a next state determined by an encoder input dₖ₊₁=i and a state Sₖ=m, and Intrₖⁱ denotes the intrinsic information.

8. The MAP decoder as claimed in claim 1, wherein the LLR L(dₖ^{q}) calculated using the branch metrics Bₖⁱ(m), the forward metrics αₖ(m), and the backward metrics βₖ(m) is expressed by a following equation,
$$L ( {d}_{k}^{q} ) = log \frac{{\sum }_{i \vert {d}_{k}^{q} = 1}^{} {\sum }_{m} {B}_{k}^{i} ( m ) {Intr}_{k}^{i} {α}_{k - 1} ( {S}_{b}^{i} ( m ) ) {β}_{k} ( m )}{{\sum }_{i \vert {d}_{k}^{q} = 0}^{} {\sum }_{m} {B}_{k}^{i} ( m ) {Intr}_{k}^{i} {α}_{k - 1} ( {S}_{b}^{i} ( m ) {β}_{k} ( m )}$$
wherein S_{b}ⁱ(m) denotes a previous state determined by an encoder input dₖ=i and a state Sₖ=m, Sₙⁱ(m) denotes a next state determined by an encoder input dₖ₊₁=i and a state Sₖ=m at a time of k−1, and Intrₖⁱ denotes the intrinsic information.

9. An apparatus used to calculate a reliability of a result of a decoding operation of a received signal, the apparatus comprising:
a receiving unit to receive relevant intrinsic information, relevant branch metrics, and relevant backward metrics; and
a reliability calculating unit to calculate a measure of the reliability, using the intrinsic information, the branch metrics and the backward metrics corresponding to the received signal.

10. An apparatus as recited in claim 9, where in the measure of reliability is a log likelihood ratio.

11. An apparatus as recited in claim 9, further comprising a forward metric operation unit to compute forward metrics based on the intrinsic information and the branch metrics.

12. An apparatus as recited in claim 11, wherein the receiving unit also receives the forward metrics and the reliability calculating unit also uses the forward metrics to calculate the measure of reliability.

13. A decoding method for a MAP decoder, comprising the operations of:
storing input intrinsic information;
calculating branch metrics of a received signal;
storing the branch metrics calculated with respect to the received signal;
calculating forward metrics by reading out the intrinsic information and the branch metrics corresponding to the received signal;
calculating backward metrics by reading out the intrinsic information and the branch metrics corresponding to the received signal; and
calculating a log likelihood ratio (LLR) using the intrinsic information, the branch metrics and the backward metrics corresponding to the received signal.

14. The decoding method as claimed 9, further comprising the operations of storing the calculated backward metrics.

15. The decoding method as claimed in claim 13, wherein a number of the branch metrics is stored on a condition that a frame length of the received signal is N and the number of input bits of an encoder is 2b is N2^{b+1}; and
wherein the branch metrics, the number of which is N2^{b+1,} are iteratively read out for a predetermined number of times in response to the received signal when the forward metrics, the backward metrics, and the LLR are calculated.

16. The decoding method as claimed in claim 13, wherein the number of the intrinsic information is N2^{2b} on condition that a frame length of the received signal is N, and number of input bits of an encoder is 2b.

17. The decoding method as claimed in claim 13, wherein the branch metrics Bₖⁱ(m) are expressed by a following equation on the condition that Xₖⁱ(m) is an output of an encoder determined by a state Sₖ₋₁=m and an encoder input dₖ=i, and Rₖ=(xₖ,yₖ) is a signal received at a time of k,
$${B}_{k}^{i} ( m ) = {σ}_{i} ( {R}_{k} , m ) = K exp ( \frac{2}{2 {σ}^{2}} {X}_{k}^{i} ( m ) ( {x}_{k} - {X}_{k}^{i} ( m ) + ( {2}^{b + 1} - 1 ) ) )$$
wherein K denotes a constant, and b denotes ½ of the number of encoder input bits.

18. The decoding method as claimed in claim 13, wherein the forward metrics αₖ(m) calculated using the branch metrics Bₖⁱ(m) are expressed by a following equation,
$${α}_{k} ( m ) = {\sum }_{i} {B}_{k}^{i} ( m ) {Intr}_{k}^{i} {α}_{k - 1} ( {S}_{b}^{i} ( m ) )$$
wherein S_{b}ⁱ(m) denotes a previous state determined by an encoder input dₖ=i and a state Sₖ=m, and Intrₖⁱ denotes the intrinsic information.

19. The decoding method as claimed in claim 13, wherein the backward metrics βₖ(m) calculated using the branch metrics Bₖⁱ(m) are expressed by a following equation,
$${β}_{k} ( m ) = {\sum }_{i} {{B}_{k + 1}^{i} ( m )}^{- 1} {Intr}_{k + 1}^{i} {β}_{k - 1} ( {S}_{n}^{i} ( m ) )$$
wherein Sₙⁱ(m) denotes a next state determined by an encoder input dₖ₊₁=i and a state Sₖ=m, and Intrₖⁱ denotes the intrinsic information.

20. The decoding method as claimed in claim 13, wherein the LLR L(dₖ^{q}) calculated using the branch metrics Bₖⁱ(m), the forward metrics αₖ(m), and the backward metrics βₖ(m) is expressed by a following equation,
$$L ( {d}_{k}^{q} ) = log \frac{{\sum }_{i \vert {d}_{k}^{q} = 1} {\sum }_{m} {B}_{k}^{i} ( m ) {Intr}_{k}^{i} {α}_{k - 1} ( {S}_{b}^{i} ( m ) ) {β}_{k} ( m )}{{\sum }_{i \vert {d}_{k}^{q} = 0} {\sum }_{m} {B}_{k}^{i} ( m ) {Intr}_{k}^{i} {α}_{k - 1} ( {S}_{b}^{i} ( m ) ) {β}_{k} ( m )}$$
wherein S_{b}ⁱ(m) denotes a previous state determined by an encoder input dₖ=i and a state Sₖ=m, Sₙⁱ(m) denotes a next state determined by an encoder input dₖ₊₁=i and a state Sₖ=m, and Intrₖⁱ denotes the intrinsic information.

21. A method used to calculate a reliability of a result of a decoding operation of a received signal, the method comprising:
receiving relevant intrinsic information, relevant branch metrics, and relevant backward metrics; and
calculating a measure of the reliability, using the intrinsic information, the branch metrics and the backward metrics corresponding to the received signal.

22. A method as recited in claim 21, where in the measure of reliability is a log likelihood ratio.

23. A method as recited in claim 21, further comprising computing forward metrics based on the intrinsic information and the branch metrics.

24. A method as recited in claim 23, wherein the receiving unit also receives the forward metrics and the reliability calculating unit also uses the forward metrics to calculate the measure of reliability.
